(19) United States
(12) Patent Application Publication
(10) Pub. No.: US 2026/0247818 A1
(43) Pub. Date: Aug. 20, 2026

(54) DISPLAY DEVICE

(71) Applicant: Sharp Display Technology Corporation, Kameyama City, Mie (JP)

(72) Inventor: Tomoo FURUKAWA, Kameyama City (JP)

(21) Appl. No.: 19/469,905

(22) PCT Filed: Apr. 10, 2023
(86) PCT No.: PCT/JP2023/014501

§ 371 Date: Sep. 26, 2025

(51) Int. Cl. H10K 59/131; H10K 59/65; H10K 59/80

(52) U.S. Cl. CPC H10K 59/131; H10K 59/65; H10K 59/80518

(57) ABSTRACT

A display device includes a display section configured to display an image with use of light emitted from a plurality of light-emitting elements. The display section includes a first display region and a second display region where light passes through a light-emitting element layer and a pixel circuit layer. The second display region includes a first light-emitting element (51) including a first electrode (21) and a second light-emitting element (52) including a second electrode (22). The first electrode is connected to a first pixel circuit via a first wiring (31), and the second electrode is connected to a second pixel circuit via a second wiring (32). The first wiring and the second wiring are light-transmissive, and the first wiring has a larger wire width than that of the second wiring.

### TECHNICAL FIELD

The present disclosure relates to a display device including a camera region formed in a display section and configured to let imaging light in.

### BACKGROUND ART

In recent years, technologies of providing, in part of display sections of display devices, light-transmitting regions that allow light to pass therethrough to back sides of the display sections while enabling displaying have been known. Such technologies are applied to, for example, display devices and the like that include camera units formed in positions overlapping the display sections and configured to capture images with use of imaging light that has passed through the display sections. Patent Literature 1 discloses a technology of forming a region that allows light to pass therethrough, on a display panel.

### Patent Literature 1

International Publication No. WO 2021/256194

### SUMMARY OF INVENTION

### Technical Problem

In a case where a light-transmitting region is formed in a display section, in the light transmitting region, electrodes serving as part of light-emitting elements including light-emitting elements and wirings for driving the electrodes may be formed in order to cause the light-transmitting region to function as part of the display section. In this case, there is a possibility that the light passing between the wirings is diffracted, and the properties of the light passing through the light-transmitting region are changed.

### Solution to Problem

A light-emitting device in accordance with an embodiment of the present disclosure is a display device including a display section configured to display an image with use of light emitted from the plurality of light-emitting elements, the display section including: a pixel circuit layer including a plurality of pixel circuits; a light-emitting element layer including a plurality of light-emitting elements, the display section including a first display region and a second display region where light passes through the light-emitting element layer and the pixel circuit layer, the second display region including a first light-emitting element including a first electrode, a second light-emitting element including a second electrode, a first wiring electrically connected to the first electrode, and a second wiring electrically connected to the second electrode, the first electrode being connected, via the first wiring, to a first pixel circuit located in an area surrounding the second display region, the second electrode being connected, via the second wiring, to a second pixel circuit located in the area surrounding the second display region, the first wiring and the second wiring being light-transmissive, the first wiring having a larger wire width than that of the second wiring.

### Advantageous Effects of Invention

Reduced is change in properties of light passing through a second display region including a light-transmitting region.

### BRIEF DESCRIPTION OF DRAWINGS

FIG. 1 is an enlarged view schematically illustrating a camera region in accordance with Embodiment 1.

FIG. 2 is a plan view schematically illustrating a display device in accordance with Embodiment 1.

FIG. 3 is an enlarged view schematically illustrating a display section of the display device in accordance with Embodiment 1, focusing on the vicinities of the camera region and a circuit region.

FIG. 4 is another enlarged view schematically illustrating the camera region in accordance with Embodiment 1.

FIG. 5 is a side cross-sectional view schematically illustrating the camera region and the circuit region of the display device in accordance with Embodiment 1.

FIG. 6 is an enlarged view schematically illustrating a camera region in accordance with Embodiment 2.

FIG. 7 is another enlarged view schematically illustrating the camera region in accordance with Embodiment 2.

FIG. 8 is an enlarged view schematically illustrating a camera region in accordance with Embodiment 3.

### DESCRIPTION OF EMBODIMENTS

### Embodiment 1

### Overview of Display Device

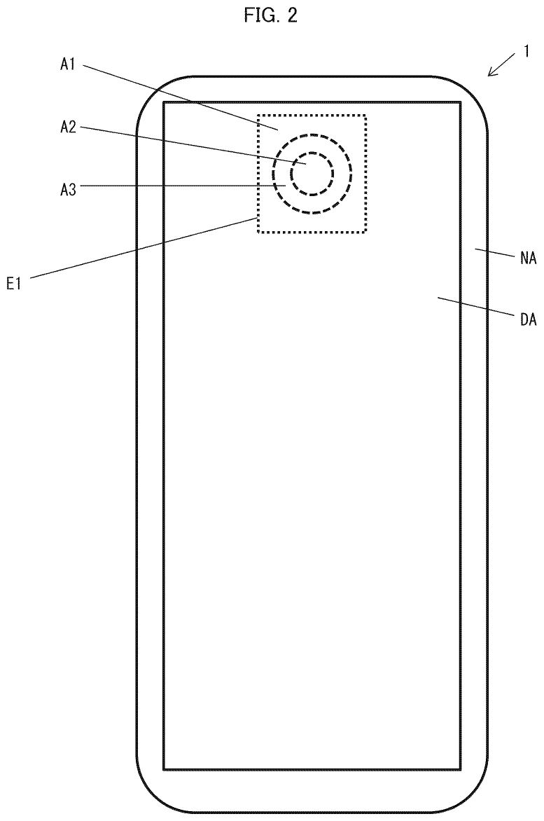

FIG. 2 is a plan view schematically illustrating a display device 1. The display device 1 includes a display section DA and a frame section NA formed along an outer periphery of the display section DA. The display device 1 displays an image on the display section DA by controlling emitted light from each of a plurality of light-emitting elements (described later) formed in the display section DA. The frame section NA may be provided with, for example, a driver formed for driving each of the plurality of light-emitting elements in the display section DA. In the present embodiment, the expression “a plan view of the display device 1” means seeing the display device 1 from a direction perpendicular to an upper surface, which is a light-emitting surface, of the display section DA of the display device 1.

The display section DA of the display device 1 in accordance with the present embodiment includes: a pixel circuit layer including a plurality of pixel circuits; and a light-emitting element layer including a plurality of light-emitting elements, as described later. For example, the display section DA includes the light-emitting elements for respective sub pixels. The light-emitting elements include, for example, pixel electrodes formed for respective sub pixels, a common electrode formed to be common to a plurality of sub pixels, and functional layers including light-emitting layers formed between the pixel electrodes and the common electrode. The display section DA performs displaying by driving the pixel electrodes on the basis of a signal inputted from the driver of the frame section NA to control emitted light from the light-emitting elements.

Hereinafter, in the display section DA, each pixel electrode is a light-reflecting electrode that reflects visible light and the common electrode is a transmissive electrode that allow visible light to pass therethrough, unless otherwise specified. Further, in a case where each light-emitting element of the display section DA is a light-emitting element, the pixel electrode is an anode of the light-emitting element, and the common electrode is a cathode of the light-emitting element. The pixel circuits for driving the pixel electrodes in the display section DA may be each composed of a member that reflects visible light.

In the present embodiment, the display section DA includes a normal display region A1 serving as a first display region, a camera region A2 serving as a second display region, and a circuit region A3. For example, the camera region A2 and the circuit region A3 are formed within the inner area of the normal display region A1. Further, the camera region A2 is formed within the circuit region A3. For example, the camera region A2 has a substantially circular shape in a plan view of the display device 1. In this case, for example, the circuit region A3 is located between the normal display region A1 and the camera region A2, and has an annular shape with a substantially constant width in a plan view of the display device 1. In other words, the circuit region A3 is located in an area surrounding the camera region A2.

### Normal Display Region

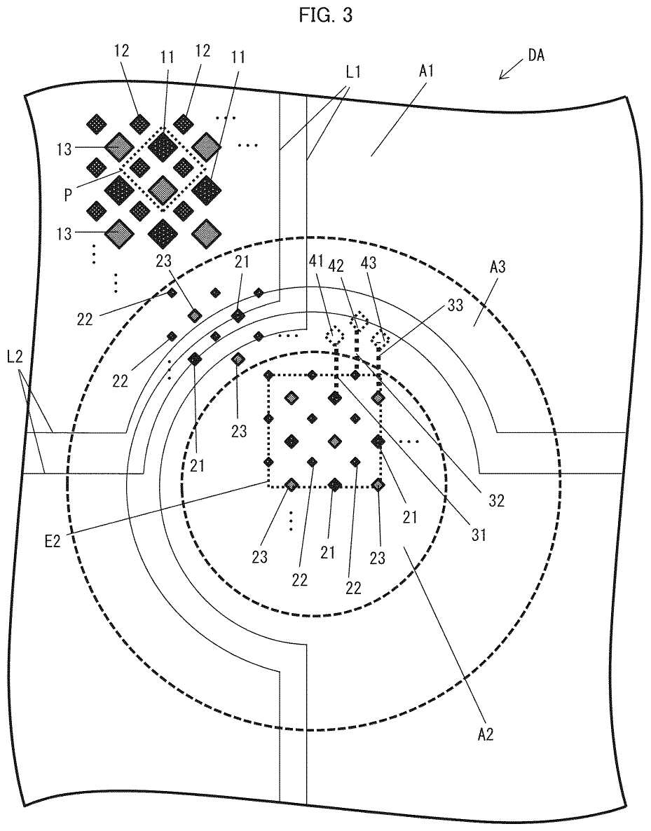

With reference to FIG. 3, the following will describe the normal display region A1, the camera region A2, and the circuit region A3 in more detail. FIG. 3 is an enlarged view schematically illustrating the region E1 illustrated in FIG. 2, in other words, an enlarged view of the display section DA, focusing on the camera region A2, the circuit region A3, and the normal display region A1 located in the vicinity of the circuit region A3. Note that in FIG. 3, only the pixel electrodes (described later) extracted from the light-emitting elements are illustrated. In other words, FIG. 3 illustrates the pixel electrodes as seen through the functional layers formed for the respective pixel electrodes and the common electrode formed to be common to the plurality of pixel electrodes.

The normal display region A1 includes, for example, a plurality of first normal light-emitting elements, a plurality of second normal light-emitting elements, and a plurality of third normal light-emitting elements. As illustrated in FIG. 3, each first normal light-emitting element includes a first normal electrode 11 as a pixel electrode, each second normal light-emitting element includes second normal electrode 12 as a pixel electrode, and each third normal light-emitting element includes third normal electrode 13 as a pixel electrode. The first normal electrodes 11, the second normal electrodes 12, and the third normal electrodes 13 are disposed two-dimensionally in the normal display region A1.

In the present embodiment, for example, the first normal light-emitting elements may emit light in a first color, the second normal light-emitting elements may emit light in a second color, and the third normal light-emitting elements may emit light in a third color. In the present specification, for example, the first color may be blue, the second color may be green, and the third color may be red. In other words, the first normal light-emitting elements may be blue light-emitting elements that emit blue light, the second normal light-emitting elements may be green light-emitting elements that emit green light, and the third normal light-emitting elements may be red light-emitting elements that emit red light.

In the present embodiment, the blue light refers to, for example, light having an emission center wavelength in a wavelength band of not smaller than 380 nm and not greater than 500 nm. Further, the green light refers to, for example, light having an emission center wavelength in a wavelength band of greater than 500 nm and not greater than 600 nm. Furthermore, the red light refers to light having an emission center wavelength in a wavelength band of greater than 600 nm and not greater than 780 nm.

The normal display region A1 includes, for example, pixel circuits, for the light-emitting elements, configured to drive the pixel electrodes. The pixel circuits may drive the pixel electrodes on the basis of signals transmitted from the driver in the frame section NA to control emitted light from the light-emitting elements. The pixel circuits may include thin film transistors formed by a method described later.

For example, the display section DA may be provided with a plurality of first signal lines L1 formed so as to extend in a substantially up-and-down direction of the display device 1 and a plurality of second signal lines L2 formed so as to extend in a left-and-right direction of the display device 1. Signals from the driver of the frame section NA may be applied to the first signal lines L1 and the second signal lines L2. Here, the normal display region A1 may include light-emitting elements at the intersections of the first signal lines L1 and the second signal lines L2. The pixel circuits may drive the light-emitting elements in response to signals from the corresponding first signal lines L1 and second signal lines L2.

In the present embodiment, a set including at least one first normal light-emitting element, at least one second normal light-emitting element, and at least one third normal light-emitting element may be regarded as a pixel P in the normal display region A1. For example, as illustrated in FIG. 3, the normal display region A1 may have a plurality of pixels P each including one first normal light-emitting element, two second normal light-emitting elements, and one third normal light-emitting element. In this case, the two second normal electrodes 12 included in the same pixel P may be short-circuited, and be driven by the same pixel circuit. In other words, the four light-emitting elements included in the pixel P may be driven by three pixel circuits.

### Camera Region and Circuit Region

The camera region A2 and the circuit region A3 include, for example, a plurality of first light-emitting elements, a plurality of second light-emitting elements, and a plurality of third light-emitting elements described later. Here, each first light-emitting element includes a first electrode 21 as a pixel electrode, each second light-emitting element includes a second electrode 22 as a pixel electrode, and each third light-emitting element includes a third electrode 23 as a pixel electrode.

The camera region A2 and the circuit region A3 further include a plurality of first wirings 31, a plurality of second wirings 32, and a plurality of third wirings 33. The first wirings 31, the second wirings 32, and the third wirings 33 are electrically connected to the first electrodes 21, the second electrodes 22, and the third electrodes 23 located in the camera region A2, respectively, and extend to the circuit region A3. The extending directions of the first wirings 31, the second wirings 32, and the third wirings 33 are substantially parallel to each other and may be, for example, a substantially up-and-down direction or a substantially left-and-right direction of the display device 1. In the present embodiment, the first wirings 31, the second wirings 32, and the third wirings 33 are each light-transmissive.

The circuit region A3 further includes a plurality of first pixel circuits 41, a plurality of second pixel circuits 42, and a plurality of third pixel circuits 43. The first pixel circuits 41, the second pixel circuits 42, and the third pixel circuits 43 are electrically connected to the first wirings 31, the second wirings 32, and the third wirings 33, respectively.

Therefore, the first pixel circuits 41 drive the first light-emitting elements located in the camera region A2 by driving the first electrodes 21 located in the camera region A2 via the first wirings 31. Further, the second pixel circuits 42 drive the second light-emitting elements located in the camera region A2 by driving the second electrodes 22 located in the camera region A2 via the second wirings 32. Furthermore, the third pixel circuits 43 drive the third light-emitting elements located in the camera region A2 by driving the third electrodes 23 located in the camera region A2 via the third wirings 33.

The first pixel circuits 41, the second pixel circuits 42, and the third pixel circuits 43 may also drive the first electrodes 21, the second electrodes 22, and the third electrodes 23 located in the circuit region A3, respectively. In other words, the pixel circuits for driving the light-emitting elements located in the camera region A2 and the circuit region A3 may be all formed in the circuit region A3.

Therefore, the first signal lines L1 and the second signal lines L2 may be not formed in the camera region A2. For example, as illustrated in FIG. 3, the first signal lines L1 and the second signal lines L2 whose extending directions overlap the camera region A2 may bypass the camera region A2 by passing through the circuit region A3. The first pixel circuits 41, the second pixel circuits 42, and the third pixel circuits 43 may drive the first electrodes 21, the second electrodes 22, and the third electrodes 23, respectively, on the basis of signals from the first signal lines L1 and the second signal lines L2 formed in the circuit region A3.

In a plan view of the display device 1, the pixel electrodes in the camera region A2 and the circuit region A3 may be smaller than the pixel electrodes in the normal display region A1. Accordingly, in a plan view of the display device 1, the light-emitting elements in the camera region A2 and the circuit region A3 may be smaller than the light-emitting elements in the normal display region A1.

### Details of Camera Region

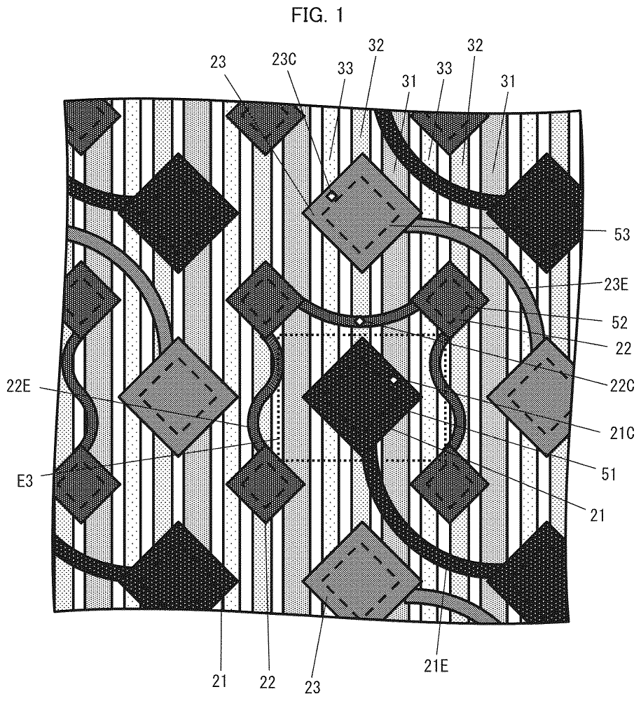

With reference to FIG. 1, the following will describe the camera region A2 in more detail. FIG. 1 is an enlarged view schematically illustrating a region E2 illustrated in FIG. 3, in other words, an enlarged view illustrating part of the camera region A2. In FIG. 1, only pixel electrodes and the wirings electrically connected to the pixel electrodes are extracted and illustrated.

In the camera region A2, functional layers are also formed in positions overlapping the first electrodes 21, the second electrodes 22, and the third electrodes 23, in a plan view of the display device 1. The common electrode is formed also in the camera region A2. Therefore, in a plan view of the display device 1, the camera region A2 is provided with first light-emitting elements 51, second light-emitting elements 52, and third light-emitting elements 53 that are formed in positions overlapping the first electrodes 21, the second electrodes 22, and the third electrodes 23, respectively.

The first light-emitting elements 51, the second light-emitting elements 52, and the third light-emitting elements 53 may be the light-emitting elements as in the case of the first normal light-emitting elements, the second normal light-emitting elements, and the third normal light-emitting elements. In this case, for example, the first light-emitting elements 51 are blue light-emitting elements that emit blue as a first color, the second light-emitting elements 52 are green light-emitting elements that emit green as a second color, and the third light-emitting elements 53 are red light-emitting element that emit red as a third color.

As illustrated in FIG. 1, the camera region A2 includes first extension sections 21E extending from the first electrodes 21, second extension sections 22E extending from the second electrodes 22, and third extension sections 23E extending from the third electrodes 23.

Here, in the camera region A2, each of the first electrodes 21 is electrically connected to another one of the first electrodes 21 via a first extension section 21E. Further, each of the second electrodes 22 is electrically connected to three other second electrodes 22 via a second extension section 22E. Furthermore, each of the third electrodes 23 is electrically connected to another one of the third electrodes 23 via a third extension section 23E.

In a plan view of the display device 1, first contact holes 21C are formed in positions where in the camera region A2 the first wirings 31 overlap the first electrodes 21 or first extension sections 21E. In particular, the first contact holes 21C each pass, in a displaying direction of the display device 1, through an organic film (described later) between the first electrodes 21 and the first extension sections 21E, and the first wirings 31. Further, at the first contact holes 21C, the first electrodes 21 or first extension sections 21E and/or the first wirings 31 are formed. Therefore, in the camera region A2 the first electrodes 21 or first extension sections 21E are electrically connected to the first wirings 31 via the first contact holes 21C.

Similarly, in a plan view of the display device 1, second contact holes 22C are formed in positions where in the camera region A2 the second wirings 32 overlap the second electrodes 22 or second extension sections 22E. In the camera region A2, the second electrodes 22 or second extension sections 22E are electrically connected to the second wirings 32 via the second contact holes 22C.

Further, similarly, in a plan view of the display device 1, third contact holes 23C are formed in positions where in the camera region A2 the third wirings 33 overlap the third electrodes 23 or third extension sections 23E. In the camera region A2, the third electrodes 23 or third extension sections 23E are electrically connected to the third wirings 33 via the third contact holes 23C.

Therefore, some of the pixel circuits formed in the circuit region A3 drive the pixel electrodes located in the camera region A2, via the wirings. Here, in the present embodiment, in the camera region A2, two first electrodes 21 are short-circuited by a first extension section 21E, four second electrodes 22 are short-circuited by a second extension section 22E, and two third electrodes 23 are short-circuited by a third extension section 23E. Therefore, some of the first pixel circuits 41 in the circuit region A3 each drive two first electrodes 21 at a time. Some of the second pixel circuits 42 in the circuit region A3 each drive four second electrodes 22 at a time. Some of the third pixel circuits 43 in the circuit region A3 each drive two third electrodes 23 at a time.

Therefore, in the display device 1, the first pixel circuit 41, the second pixel circuit 42, and the third pixel circuit 43 in the circuit region A3 control emitted light from two first light-emitting elements 51, emitted light from four second light-emitting elements 52, and emitted light from two third light-emitting elements 53, respectively. Thus in the camera region A2, a set including two first light-emitting elements 51, four second light-emitting elements 52, and two third light-emitting elements 53 may be regarded as a pixel P. This enables the display device 1 to reduce the number of the pixel circuits in the circuit region A3 needed for controlling the light-emitting elements included in one pixel P in the camera region A2 to be smaller than the number of the pixel circuits needed for controlling the light-emitting elements included in one pixel P in the normal display region A1.

The pixel circuits for driving the electrodes located in the camera region A2 may be located closer to a side of any of the extending directions of the wirings than the electrodes. For example, in a plan view of the display device 1, in a case where the first wirings 31 extend in an up-and-down direction, the first pixel circuits 41 connected to the first electrodes 21 via the first wirings 31 may be located upper than the first electrodes 21 or may be located lower than the first electrodes 21.

For example, in a plan view of the display device 1, the pixel circuits for driving the electrodes located in the upper half of the camera region A2 may be located in the upper half of the circuit region A3. On the other hand, for example, in a plan view of the display device 1, the pixel circuits for driving the electrodes located in the lower half of the camera region A2 may be located in the lower half of the circuit region A3.

Alternatively, extending directions of some of the wirings in the camera region A2 and in the circuit region A3 may be different from extending directions of others of the wirings. For example, in a plan view of the display device 1, the wirings connected to the electrodes located in the vicinity of the left and right edges of the camera region A2 may extend in a left-and-right direction. The pixel circuits for driving such electrodes may be located on either the left or right side of the circuit region A3 in a plan view of the display device 1.

In a plan view of the first electrodes 21, the first contact holes 21C and the first light-emitting elements 51 do not overlap. Therefore, the first contact holes 21C and the first electrodes 21 or first wirings 31 formed at the first contact holes 21C are less likely to affect light from the first light-emitting elements 51.

In a plan view of the second electrodes 22, the second contact holes 22C do not overlap the second light-emitting elements 52, and in a plan view of the third electrodes 23, the third contact holes 23C do not overlap the third light-emitting elements 53. In particular, the second contact holes 22C at which the second electrodes 22 and the second wirings 32 are connected are formed in positions overlapping the second extension sections 22E extending from the second electrodes 22 in a plan view of the second electrodes 22. Thus, forming the contact holes in positions overlapping the extension sections in a plan view of any pixel electrodes in the camera region A2 makes it possible to further reduce the impact of the contact holes on light from the light-emitting elements in the camera region A2.

### Wire Widths of Wirings

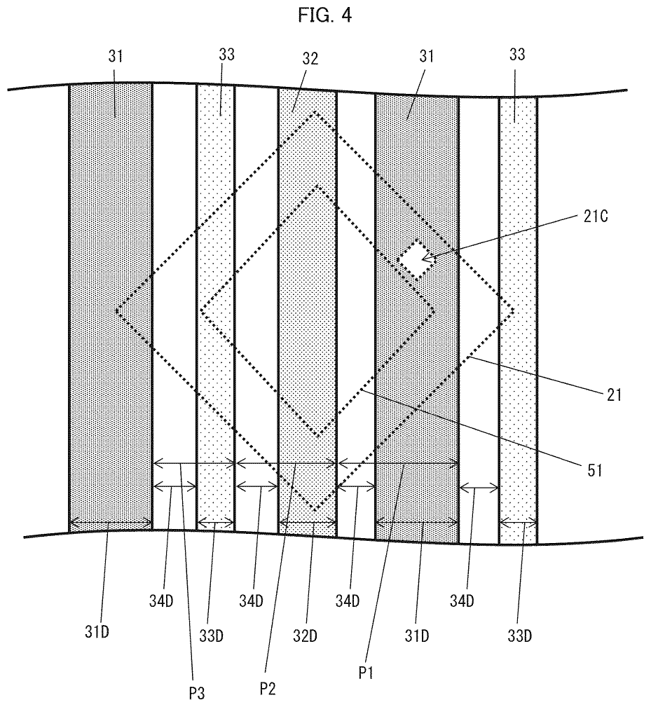

With reference to FIG. 4, the following will describe the pixel electrodes, the wirings, and the light-emitting elements in the camera region A2 in more detail. FIG. 4 is an enlarged view schematically illustrating the region E3 illustrated in FIG. 1, in other words, an enlarged view illustrating one first electrode 21 and wirings in the vicinity of the first electrode 21. FIG. 4 illustrates only the wirings as seen through the first light-emitting element 51.

In particular, FIG. 4 illustrates the first electrode 21 and the first light-emitting element 51 with dotted lines. This indicates that in FIG. 4, the first electrode 21 and the first light-emitting element 51 are located closer to the front side with respect to the drawing of FIG. 4 than the first wiring 31, the second wiring 32, and the third wiring 33. In other words, in the display device 1, the first electrode 21 and the first light-emitting element 51 are located closer to a side of a direction in which light from the light-emitting elements in the display device 1 exits than the first wiring 31, second wiring 32, and third wiring 33.

As illustrated in FIG. 4, in a plan view of the display device 1, the first wiring 31, the second wiring 32, and the third wiring 33 have a wire width 31D, a wire width 32D, and a wire width 33D, respectively. In the present embodiment, the wire width 31D is larger than the wire width 32D, and the wire width 32D is larger than the wire width 33D. In other words, the wire width 31D of the first wiring 31, the wire width 32D of the second wiring 32, and the wire width 33D of the third wiring 33 are different from each other.

As illustrated in FIG. 4, the first wiring 31 and the second wiring 32 are adjacent to and parallel to each other. Further, the second wiring 32 and the third wiring 33 are adjacent to and parallel to each other. In the present embodiment, the gap between the first wiring 31 and the second wiring 32 and the gap between the second wiring 32 and the third wiring 33 may each have a width 34D.

The camera region A2 may include: fourth light-emitting elements including fourth electrodes; and fourth wirings electrically connected to the fourth electrodes. Here, each third wiring 33 and each fourth wiring may be adjacent to and parallel to each other on a side opposite from the second wiring 32. In this case, the fourth wiring may be a first wiring 31 other than the first wiring 31 adjacent to the second wiring 32. In other words, the fourth electrode and the fourth light-emitting element may be a first electrode 21 other than the first electrode 21 connected to the first wiring 31 adjacent to the second wiring 32, and the first light-emitting element 51 including the other first electrode 21, respectively. In this case, the fourth wirings are light-transmissive and have the same wire width as that of the first wirings 31. The gap between the third wiring 33 and the fourth wiring, in other words, the gap between the third wiring 33 and the first wiring 31 adjacent to the third wiring, may have the width 34D.

As illustrated in FIG. 4, the first wiring 31, the second wiring 32, and the third wiring 33 overlap the first electrode 21, in a plan view of the first electrode 21. In other words, the first wiring 31, the second wiring 32, and the third wiring 33 are not needed to be formed so as to be prevented from overlapping the pixel electrodes in the camera region A2, in a plan view of the first electrode 21. This enables the display device 1 to simplify the design of the first wirings 31, the second wirings 32, and the third wirings 33 and also further increase the wire widths thereof.

The configurations of the pixel electrodes, the wirings, and the light-emitting elements in the circuit region A3 may be the same as the configurations of the pixel electrodes, the wirings, and the light-emitting elements in the camera region A2, except that the wirings are connected to the pixel circuits.

### Layer Structure

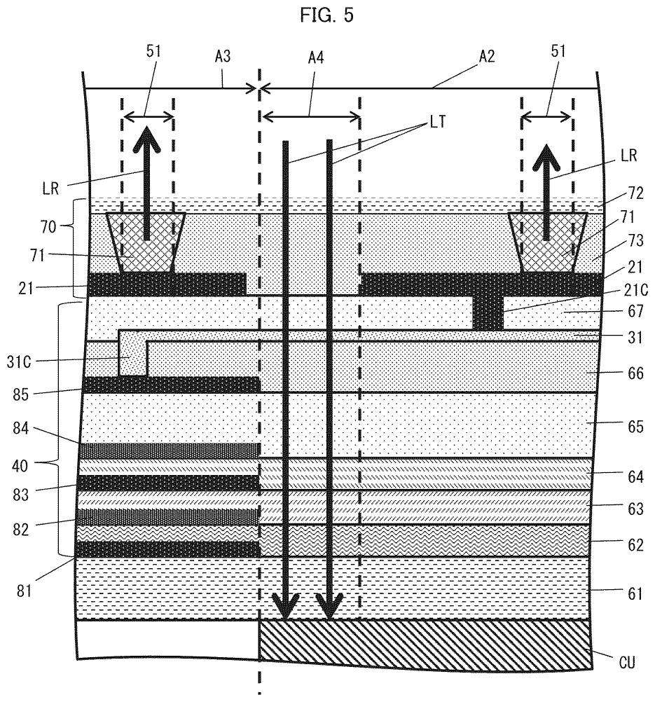

With reference to FIG. 5, the following will describe a layer structure of the display device 1 in the camera region A2 and the circuit region A3 in detail. FIG. 5 is an enlarged side cross-sectional view schematically illustrating a side cross-section taken along a plane substantially perpendicular to the display surface of the display device 1, focusing on the vicinity of the camera region A2 and the circuit region A3.

The display device 1 includes a light-transmissive substrate 61, including, for example, a glass substrate or a film substrate. Further, the display device 1 includes a pixel circuit layer 40 on the substrate 61. The pixel circuit layer 40 includes, in order from a substrate 61 side, a first inorganic interlayer film 62, a second inorganic interlayer film 63, a third inorganic interlayer film 64, a first organic interlayer film 65, a second organic interlayer film 66, and a third organic interlayer film 67 each of which is light-transmissive. The aforementioned substrate 61, inorganic interlayer films, and organic interlayer films may be formed in the display section DA including the normal display region A1, the camera region A2, and the circuit region A3.

The first inorganic interlayer film 62, the second inorganic interlayer film 63, and the third inorganic interlayer film 64 are formed, for example, by forming an inorganic oxide film or the like by a CVD method or the like. The first organic interlayer film 65, the second organic interlayer film 66, and the third organic interlayer film 67 are formed, for example, by applying a light-transmissive organic coating film, such as polyimide, by a coating method, a photolithography method, or the like.

Further, the display device 1 includes a light-emitting element layer 50 located in a layer above the pixel circuit layer 40. The light-emitting element layer 50 includes a plurality of light-emitting elements including the first light-emitting elements 51. The light-emitting element layer 50 includes the pixel electrodes of the light-emitting elements, functional layers including light-emitting layers, and the common electrode formed to be common to the light-emitting elements, in this order from a pixel circuit layer 40 side. In particular, the light-emitting element layer 50 is formed by the first electrodes 21, first functional layers 71, and a common electrode 72, and includes the first light-emitting elements 51 that emit light in a first color.

The light-emitting element layer 50 may further include a bank layer 73 on the third organic interlayer film 67 of the pixel circuit layer 40 and on the pixel electrodes of the light-emitting elements. In this case, in a plan view of the display device 1, openings may be formed in positions overlapping the sub pixels of the bank layer 73, and functional layers of the light-emitting elements may be formed in the openings. The bank layer 73 may be formed, for example, by applying a light-transmissive organic coating film, such as polyimide, by a coating method, a photolithography method, or the like.

In the present embodiment, the pixel electrodes in the camera region A2 and the circuit region A3, including the first electrodes 21, are formed between the third organic interlayer film 67 and the bank layer 73. In the present embodiment, the wirings in the camera region A2 and the circuit region A3, including the first wirings 31, are formed between the second organic interlayer film 66 and the third organic interlayer film 67.

Therefore, the contact holes in the camera region A2 and the circuit region A3, including the first contact holes 21C, are formed in the third organic interlayer film 67. For example, as illustrated in FIG. 5, the first electrode 21 may be formed at the first contact hole 21C, thereby implementing the first electrode 21 and the first wiring 31 via the first contact hole 21C.

In a case where the first electrodes 21 are anodes of light-emitting elements serving as the first light-emitting elements 51, the first functional layers 71 may each include, for example, a hole transfer layer, a light-emitting layer, and an electron transfer layer in this order from a first electrode 21 side. In this case, the light-emitting layer may be, for example, an organic light-emitting layer containing an organic light-emitting material. Alternatively, the light-emitting layer may be, for example, a quantum-dot light-emitting layer containing semiconductor nanoparticles, in other words, quantum dots, as a light-emitting material.

Further, in the circuit region A3, the pixel circuit layer 40 includes, in order from a substrate 61 side, a first conductive film 81, a semiconductor film 82, a second conductive film 83, a third conductive film 84, and a fourth conductive film 85. The first conductive film 81 is located between the substrate 61 and the first inorganic interlayer film 62. The semiconductor film 82 is located between the first inorganic interlayer film 62 and the second inorganic interlayer film 63. The second conductive film 83 is located between the second inorganic interlayer film 63 and the third inorganic interlayer film 64. The third conductive film 84 is located between the third inorganic interlayer film 64 and the first organic interlayer film 65. The fourth conductive film 85 is located between the first organic interlayer film 65 and the second organic interlayer film 66. The aforementioned conductive films and semiconductor film 82 may be formed not only in the pixel circuit layer 40 in the circuit region A3 but also in the pixel circuit layer 40 in the normal display region A1.

The first conductive film 81, the second conductive film 83, the third conductive film 84, and the fourth conductive film 85 are each electrically conductive, and may be, for example, light-reflective conductive films including metal films. The pixel circuits in the circuit region A3 may be formed by forming thin film transistors with use of the first conductive film 81, the semiconductor film 82, the second conductive film 83, the third conductive film 84, and the fourth conductive film 85. The conductive films and the semiconductor film 82 may also form the pixel circuits for driving the pixel electrodes in the normal display region A1.

The pixel circuits in the circuit region A3 and the pixel electrodes in the camera region A2 may be electrically connected by electrically connecting the fourth conductive film 85 in the circuit region A3 and the pixel electrodes in the camera region A2 via the wirings. In this case, for example, as illustrated in FIG. 5, circuit region contact holes 31C may be formed in the second organic interlayer film 66, and the fourth conductive film 85 and the first wirings 31 may be electrically connected via the circuit region contact holes 31C.

In the present embodiment, as illustrated in FIG. 4, for example, the first pixel circuits 41 for driving the first light-emitting elements 51 are formed by the layers from the first conductive film 81 to the fourth conductive film 85 in the circuit region A3. Further, the fourth conductive film 85 of the first pixel circuit 41 is electrically connected to the first electrodes 21 in the camera region A2 via the first wirings 31. Thus, the first pixel circuits 41 control emitted light LR from the first light-emitting elements 51 in the camera region A2 by driving the first electrodes 21 in the camera region A2.

### Introduction of Imaging Light Into Camera

In the camera region A2, the display device 1 further includes a camera unit CU including imaging elements, on an opposite side of the substrate 61 from the pixel circuit layer 40, in other words, on a side of a layer below the pixel circuit layer 40. The imaging light LT incident from a display surface side of the display device 1 enters the camera unit CU. In particular, in the camera region A2, the light-transmissive members including the wirings, except for the pixel electrodes and the extension sections, are formed. Therefore, a light-transmitting region A4 through which the imaging light LT passes from the common electrode 72 to the camera unit CU is formed between the pixel electrodes and between the extension sections in the camera region A2.

Therefore, the imaging light LT that has entered the light-transmitting region A4 from a display surface side of the display device 1 is introduced into the camera unit CU. In other words, the camera region A2 including the light-transmitting region A4 serves as a daylighting display region for letting external light in.

This enables the display device 1 to capture images of objects on a side closer to the display surface than the substrate 61 with use of the camera unit CU. The display device 1 may also capture images of objects from the back side of the display device 1, that is, the side opposite from the display surface with respect to the substrate 61 with use of the camera unit CU.

As described above, the imaging light LT from the display surface side of the display device 1 is introduced into the camera unit CU in the light-transmitting region A4 located between the pixel electrodes and between the extension sections in the camera region A2. Therefore, the imaging light LT introduced into the camera unit CU passes through the wirings or gaps between the wirings in the camera region A2.

### Interference of Diffracted Light Beams of Imaging Light

Here, the following will examine an impact of the wirings in the camera region A2 on the imaging light LT introduced into the camera unit CU.

For example, it is assumed that the wirings in the camera region A2 have the same wire width and the gaps between adjacent wirings also have the same width. In this case, the wirings are periodically disposed in a wire width direction of the wirings in the light-transmitting region A4. In other words, when the light-transmitting region A4 is seen in a wire width direction of the wirings, a part where a wiring is formed and a part where no wiring is formed exist periodically at an interval of the pitch described above.

The imaging light LT that has entered the light-transmitting region A4 may be diffracted when passing through the wirings and the areas therebetween, and the diffracted light beams may interfere with each other. In other words, the properties of the light passing through the camera region A2 may change when the light passes through the wirings and the areas therebetween. Here, in a case where the wire widths of the wirings in the camera region A2 are the same, the periodicity of the presence or absence of the wirings in the wire width direction of the wirings in the light-transmitting region A4 may cause the wirings to function as a diffraction grating, thereby intensifying the interference of the diffracted light beams described above.

In a case where the plurality of imaging light beams LT introduced into the camera unit CU interfere with each other, light at a specific wavelength may be intensified or attenuated, resulting in decrease in imaging quality of the camera unit CU. In particular, in a case where the wirings are adjacent to and parallel to each other, the aforementioned interference may become further intensified.

### Reduction of Interference of Diffracted Light

In the present embodiment, the wire width 31D of the first wirings 31, the wire width 32D of the second wirings 32, and the wire width 33D of the third wirings 33 are different from each other. This reduces the periodicity of the presence or absence of the wirings in the light-transmitting region A4 in a wire width direction of the wirings. Accordingly, the display device 1 in accordance with the present embodiment makes it possible to reduce the interference between diffracted light beams of the imaging light LT passing through the wirings and the areas therebetween.

In other words, the display device 1 in accordance with the present embodiment makes it possible to reduce change in the properties of light passing through the camera region A2. This enables the display device 1 to reduce the impact of the wirings on the light that has entered the camera region A2 from the display surface, including the light introduced from the display surface side.

In particular, the display device 1 reduces the interference between diffracted light beams of the imaging light LT introduced into the camera unit CU through the camera region A2, particularly from the light-transmitting region A4, thereby reducing the degradation in imaging quality of the camera unit CU. Therefore, the display device 1 makes it possible to, while performing displaying in the camera region A2, reduce an impact on capturing of an image by the imaging elements in the camera region A2.

In the present embodiment, the wire width 31D, the wire width 32D, and the wire width 33D are different from each other, but this should not be construed as a limitation. For example, the wire width 31D and the wire width 32D may differ from each other, and the wire width 33D may be the same as the wire width 31D or the wire width 32D. Even in this case, the periodicity, between the first wirings 31 and the second wirings 32, of the presence or absence of the wirings in the wire width direction of the wirings is reduced, thereby reducing the interference between the diffracted light beams of the imaging light LT.

Here, as illustrated in FIG. 4, in the wire width direction of the wirings, a distance from one end of the first wiring 31 on an opposite side from the other end thereof which faces the second wiring 32 to one end of the second wiring 32 which faces the first wiring 31 is defined as a first pitch P1. Further, a distance from one end of the second wiring 32 on an opposite side from the other end thereof which faces the third wiring 33 to one end of the third wiring 33 which faces the second wiring 32 is defined as a second pitch P2. Furthermore, a distance from one end of the third wiring 33 on an opposite side from the other end thereof which faces the first wiring 31 to one end of the first wiring 31 which faces the third wiring 33 is defined as a third pitch P3. In this case, the first pitch P1 is a total of the wire width 31D and the width 34D, the second pitch P2 is a total of the wire width 32D and the width 34D, and the third pitch P3 is a total of the wire width 33D and the width 34D.

In the present embodiment, the wire width 31D, the wire width 32D, and the wire width 33D are different from each other, whereas the width 34D of the gaps between the pairs of adjacent wirings is the same. Therefore, the aforementioned first pitch P1, second pitch P2, and third pitch P3 differ from each other. This enables the display device 1 in accordance with the present embodiment to further reduce the periodicity of the presence or absence of the wirings in the wire width direction of the wirings. Therefore, the display device 1 makes it possible to further reduce the interference between diffracted light beams of the imaging light LT introduced into the camera unit CU from the camera region A2, particularly from the light-transmitting region A4, and further reduce the degradation in imaging quality of the camera unit CU.

### Supplements

In the present embodiment, the first wirings 31 and the second wirings 32; the second wirings 32 and the third wirings 33; and the third wirings 33 and the first wirings 31 are adjacent to and parallel to each other respectively. This enables the display device 1 to reduce the interference between the diffracted light beams of the imaging light LT introduced into the camera unit CU, while simplifying the arrangement of the wirings in the camera region A2. However, this should not be construed as a limitation. The first wirings 31, the second wirings 32, and the third wirings 33 may be each not parallel to other wirings, or may each have, for example, a curved portion.

In the present embodiment, the wire width 31D is larger than the wire width 32D, and the wire width 32D is larger than the wire width 33D. In other words, the wire width of the first wirings 31 connected to the first electrodes 21 of the first light-emitting elements 51 is larger than the wire width of the second wirings 32 connected to the second electrodes 22 of the second light-emitting elements 52. Further, the wire width of the second wirings 32 connected to the second electrodes 22 of the second light-emitting elements 52 is larger than the wire width of the third wirings 33 connected to the third electrodes 23 of the third light-emitting elements 53.

Here, as described above, it is assumed that the first light-emitting elements 51 are blue light-emitting elements that emit blue light, the second light-emitting elements 52 are green light-emitting elements that emit green light, and the third light-emitting elements 53 are red light-emitting elements that emit red light. In general, the light-emitting efficiency of the light-emitting elements tends to be higher in order of the blue light-emitting elements, the green light-emitting elements, and the red light-emitting elements. In other words, the amount of an electric current needed to be applied to the light-emitting elements in order to achieve emitted light with the same intensity from the light-emitting elements tends to be lower in the order of the blue light-emitting elements, the green light-emitting elements, and the red light-emitting elements.

Therefore, in the present embodiment, the amount of an electric current through the first wirings 31 may be larger than the amount of an electric current through the second wirings 32. This makes it possible to more efficiently control emitted light from the first light-emitting elements 51 serving as blue light-emitting elements requiring a higher amount of an electric current than the second light-emitting elements 52 serving as green light-emitting elements. Further, the wire width 31D of the first wirings 31, which carry an electric current in a higher amount, is larger than the wire width 32D of the second wirings 32. This enables the display device 1 to apply a higher electric current to the first electrodes 21 more efficiently and control the emitted light from the first light-emitting elements 51 more efficiently.

In the present embodiment, the amount of an electric current through the second wirings 32 may be greater than the amount of an electric current through the third wirings 33. This makes it possible to more efficiently control the emitted light from the second light-emitting elements 52 serving as green light-emitting elements requiring a higher amount of an electric current than the third light-emitting elements 53 serving as red light-emitting elements. Further, the wire width 33D of the third wirings 33, which carry an electric current in a higher amount, is larger than the wire width 32D of the second wirings 32. This enables the display device 1 to apply a higher electric current to the second electrodes 22 more efficiently and control the emitted light from the second light-emitting elements 52 more efficiently.

In the present embodiment, the first electrodes 21, the second electrodes 22, and the third electrodes 23 in the camera region A2 and the circuit region A3 are each a light-reflecting electrode. Therefore, the display device 1 can more efficiently output the light emitted from the light-emitting elements, to the display surface side by reflecting, at the pixel electrodes, the light from the light-emitting layers of the light-emitting elements in the camera region A2 and the circuit region A3. On the other hand, in the camera region A2, the light-transmitting region A4, which is a light-transmissive region, is formed between the pixel electrodes and between the extension sections, thereby enabling the camera region A2 to efficiently let the imaging light LT in the camera unit CU.

The first pixel circuits 41, the second pixel circuits 42, and the third pixel circuits 43, which are electrically connected respectively to the first electrodes 21, the second electrodes 22, and the third electrodes 23 in the camera region A2, are each located in the circuit region A3 in an area surrounding the camera region A2 in a plan view of the display device 1. This enables the display device 1 to reduce the impact of the pixel circuits on the capturing of the imaging light LT in the camera region A2, even in a case where the first pixel circuits 41, the second pixel circuits 42, and third pixel circuits 43 include light-reflective members.

### Embodiment 2

### Embodiment of Different Gaps of Wirings

The following will describe other embodiments of the present disclosure. For convenience of description, any members of the embodiments that are identical in function to the members described for Embodiment 1 are assigned the same reference signs, and are not described again here.

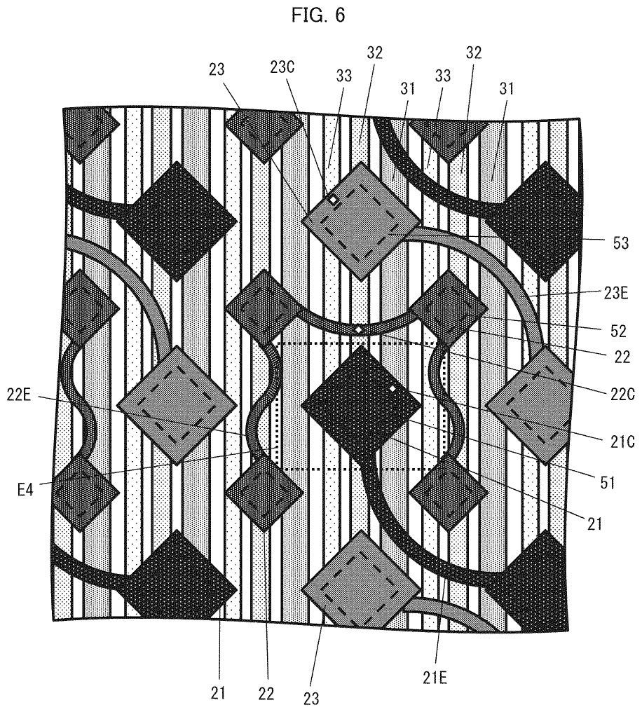

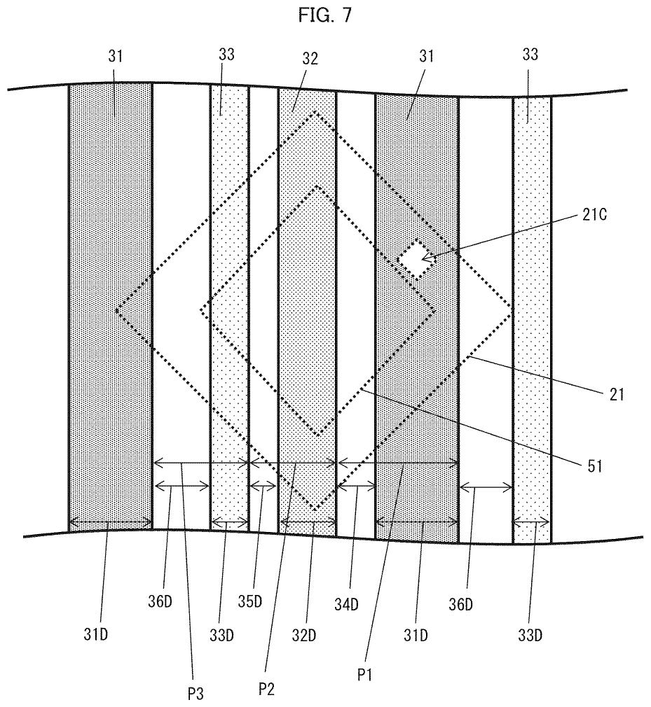

A display device 1 in accordance with the present embodiment differs from the display device 1 in accordance with the previous embodiment only in positions where the wirings are formed in the camera region A2. With reference to FIG. 6 and FIG. 7, the following will describe the positions where the wirings are formed in the camera region A2 in accordance with the present embodiment in detail.

FIG. 6 is an enlarged view schematically illustrating part of the camera region A2 in accordance with the present embodiment, in particular, an enlarged view illustrating the same position as that illustrated in FIG. 1. In FIG. 6, as in the case of FIG. 1, only the pixel electrodes and the wirings electrically connected to the pixel electrodes are extracted and illustrated.

FIG. 7 is an enlarged view schematically illustrating the region E4 illustrated in FIG. 6, in other words, an enlarged view illustrating one first electrode 21 and wirings in the vicinity of the first electrode 21. As in the case of FIG. 4, FIG. 7 illustrates only the wirings as seen through the first light-emitting element 51.

In the present embodiment, in particular, the third wiring 33 is located closer to the second wiring 32. Therefore, as illustrated in detail in FIG. 7, a width 35D of the gap between the second wiring 32 and the third wiring 33 adjacent to each other is smaller than the width 34D of the gap between the first wiring 31 and the second wiring 32 adjacent to each other. On the other hand, a width 35D of the gap between the third wiring 33 and the first wiring 31 adjacent to each other is larger than the width 34D of the gap between the first wiring 31 and the second wiring 32 adjacent to each other.

In the present embodiment, in the camera region A2, not only the wire widths of the wirings, but also the widths of the gaps of adjacent wirings are different. This further reduces the periodicity of the presence or absence of the wirings in the light-transmitting region A4 in a wire width direction of the wirings. Accordingly, the display device 1 in accordance with the present embodiment also makes it possible to reduce the interference between diffracted light beams of the imaging light LT passing through the wirings and the areas therebetween. Thus, in the present embodiment as well, the display device 1 reduces the interference between diffracted light beams of the imaging light LT introduced into the camera unit CU from the camera region A2, particularly from the light-transmitting region A4, and reduces the degradation in imaging quality of the camera unit CU.

In the present embodiment, the width 34D, the width 35D, and the width 36D are different from each other, but this should not be construed as a limitation. It is sufficient that, for example, a width of the gap between at least one pair of adjacent wirings differs from a width of the gap between other adjacent wirings.

In the present embodiment as well, the first pitch P1, the second pitch P2, and the third pitch P3 may be different from each other. In this case, the display device 1 in accordance with the present embodiment further reduces the periodicity of the presence or absence of the wirings in the wire width direction and further reduces the degradation in imaging quality of the camera unit CU.

In the present embodiment as well, the amount of an electric current through the first wirings 31 may be larger than the amount of an electric current through the second wirings 32, and the amount of an electric current through the second wirings 32 may be larger than the amount of an electric current through the third wirings 33. Making the width 36D larger than the width 34D makes it possible to reduce the impact of a short circuit between the first wirings 31 which carry an electric current in a larger amount than the other wirings, and the wirings adjacent to the first wirings 31. Further, making the width 34D larger than the width 35D makes it possible to reduce the impact of a short circuit between the second wirings 32 which carry an electric current in a larger amount than the third wirings 33, and the first wirings 31 which are adjacent to the second wirings 32 and carry an electric current in a larger amount.

### Embodiment 3

### Embodiment of Different Path Lengths of Wirings

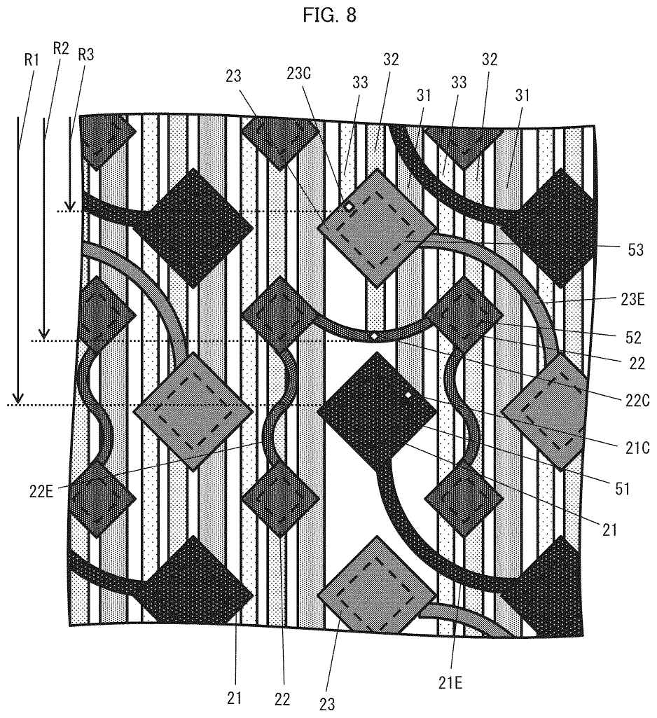

A display device 1 in accordance with the present embodiment differs from the display device 1 in accordance with the previous embodiment only in path lengths of the wirings in the camera region A2. With reference to FIG. 8, the following will describe the path lengths of the wirings in the camera region A2 in accordance with the present embodiment in detail.

FIG. 8 is an enlarged view schematically illustrating part of the camera region A2 in accordance with the present embodiment, in particular, an enlarged view illustrating the position as that illustrated in FIG. 1 or FIG. 6. In FIG. 8, as in the case of FIG. 1 or FIG. 6, only the pixel electrodes and the wirings electrically connected to the pixel electrodes are extracted and illustrated. Here, the pixel circuits for driving the electrodes connected to the wirings at the contact holes which are illustrated in FIG. 8 are located on an upper side than the electrodes in a plan view of the display device 1.

As illustrated in FIG. 8, the first wiring 31 in accordance with the present embodiment is formed only on an upper side than a position where the first electrode 21 is connected thereto at the first contact hole 21C, in a plan view of the display device 1. In other words, the first wiring 31 is formed only in an area from the first electrode 21 electrically connected thereto to the first pixel circuit 41, in a plan view of the display device 1.

Similarly, the second wiring 32 in accordance with the present embodiment is formed only on an upper side than a position where the second electrode 22 is connected thereto at the second contact hole 22C, in a plan view of the display device 1. Further, the third wiring 33 in accordance with the present embodiment is formed only on an upper side than a position where the third electrode 23 is connected thereto at the third contact hole 23C, in a plan view of the display device 1.

Therefore, in the present embodiment, the first wiring 31, the second wiring 32, and the third wiring 33 are different from each other in path lengths corresponding to the distances from the respective pixel circuits to the respective electrodes. For example, as illustrated in FIG. 8, the path length R1 of the first wiring 31 is larger than the path length R2 of the second wiring 32, and the path length R2 is larger than the path length R3 of the third wiring 33.

In the present embodiment as well, the wire widths of the wirings in the camera region A2 are different from each other. Thus, in the present embodiment as well, the display device 1 reduces the interference between diffracted light beams of the imaging light LT introduced into the camera unit CU from the camera region A2, particularly from the light-transmitting region A4, and reduces the degradation in imaging quality of the camera unit CU.

Additionally, in the present embodiment, the path lengths of the wirings in the camera region A2 are different from each other. This enables the display device 1 in accordance with the present embodiment to increase the regions where no wirings are formed, as well as further reduce the periodicity of the presence or absence of the wirings in the wire width direction of the wirings in the camera region A2.

In the regions of the light-transmitting region A4 where no wirings are formed, the imaging light LT is introduced into the camera unit CU without passing through the wirings. Therefore, in such regions, the attenuation or dispersion of the imaging light LT caused by the wirings is reduced, thereby making it possible to enhance imaging quality in these regions. Therefore, the display device 1 in accordance with the present embodiment makes it possible to reduce the degradation in imaging quality of the camera unit CU and more efficiently let the imaging light LT in the camera region A2.

The present disclosure is not limited to the above-described embodiments, but can be altered by a skilled person in the art within the scope of the claims. The present disclosure also encompasses, in its technical scope of the present disclosure, any embodiment derived by combining technical means disclosed in differing embodiments as appropriate. Further, a novel technical feature can be created by a combination of technical means disclosed in these embodiments.

### REFERENCE SIGNS LIST

1 Display device
21 First electrode
22 Second electrode
23 Third electrode
31 First wiring
32 Second wiring
33 Third wiring
40 Pixel circuit layer
41 First pixel circuit
42 Second pixel circuit
43 Third pixel circuit
50 Light-emitting element layer
51 First light-emitting element
52 Second light-emitting element
53 Third light-emitting element
A1 Normal display region (first display region)
A2 Camera region (second display region)
DA Display section

1: A display device comprising
a display section configured to display an image with use of light emitted from the plurality of light-emitting elements,
the display section comprising:
a pixel circuit layer including a plurality of pixel circuits; and
a light-emitting element layer including a plurality of light-emitting elements,
the display section including a first display region and a second display region where light passes through the light-emitting element layer and the pixel circuit layer,
the second display region including
a first light-emitting element including a first electrode,
a second light-emitting element including a second electrode,
a first wiring electrically connected to the first electrode, and
a second wiring electrically connected to the second electrode,
the first electrode being connected, via the first wiring, to a first pixel circuit located in an area surrounding the second display region,
the second electrode being connected, via the second wiring, to a second pixel circuit located in the area surrounding the second display region,
the first wiring and the second wiring being light-transmissive, the first wiring having a larger wire width than that of the second wiring.

2: The display device according to claim 1, wherein
the first display region is a normal display region, and
the second display region is a daylighting display region that lets external light in.

3: The display device according to claim 1, wherein the first wiring and the second wiring are adjacent to each other and parallel to each other.

4: The display device according to claim 1, wherein the first light-emitting element emits light in a first color, and the second light-emitting element emits light in a second color different from the first color.

5: The display device according to claim 3, wherein
the second display region includes
a third light-emitting element including a third electrode and
a third wiring electrically connected to the third electrode, and
the third wiring is light-transmissive and has a smaller wire width than that of the first wiring and that of the second wiring.

6: The display device according to claim 5, wherein the second wiring and the third wiring are adjacent to each other and parallel to each other.

7: The display device according to claim 5, wherein
the first light-emitting element emits light in a first color,
the second light-emitting element emits light in a second color different from the first color, and
the third light-emitting element emits light in a third color different from the first color and different from the second color.

8: The display device according to claim 5, wherein a width of a gap between the first wiring and the second wiring is different from a width of a gap between the second wiring and the third wiring.

9: The display device according to claim 8, wherein
the second display region includes
a fourth light-emitting element including a fourth electrode and
a fourth wiring electrically connected to the fourth electrode,
the fourth wiring is light-transmissive and has the same wire width as that of the first wiring, and
the third wiring and the fourth wiring are adjacent to each other and parallel to each other.

10: The display device according to claim 9, wherein
a width of a gap between the third wiring and the fourth wiring is larger than the width of the gap between the first wiring and the second wiring, and
the width of the gap between the first wiring and the second wiring is larger than the width of the gap between the second wiring and the third wiring.

11: The display device according to claim 7, wherein
the first color is blue,
the second color is green, and
the third color is red.

12: The display device according to claim 1, wherein an amount of an electric current through the first wiring is larger than an amount of an electric current through the second wiring.

13: The display device according to claim 2, wherein
the light-emitting element layer is located in a layer above the pixel circuit layer, and
an imaging element overlapping the second display region in a plan view is provided on a side of a layer below the pixel circuit layer.

14. : The display device according to claim 1, wherein the first electrode and the second electrode are anodes.

15: The display device according to claim 14, wherein the first electrode and the second electrode are light-reflecting electrodes.

16: The display device according to claim 1, wherein the first electrode overlaps the first wiring and the second wiring in a plan view.

17: The display device according to claim 1, wherein the first wiring has a larger path length than a path length of the second wiring.

18: The display device according to claim 1, wherein the second display region includes a first extension section extending from the first electrode and a second extension section extending from the second electrode.

19: The display device according to claim 18, wherein
the first wiring is connected to the first electrode or the first extension section via a first contact hole, and
the second wiring is connected to the second electrode or the second extension section via a second contact hole.

20: The display device according to claim 1, wherein the first light-emitting element and the second light-emitting element each include an organic light-emitting layer or a quantum-dot light-emitting layer.
